(19) United States
(12) Patent Application Publication
(10) Pub. No.: US 2025/0008685 A1
(43) Pub. Date: Jan. 2, 2025

(54) FAN MODULES FOR ELECTRONIC DEVICES

(71) Applicant: Intel Corporation, Santa Clara, CA (US)

(72) Inventors: Jeff Ku, Taipei (TW); Nirmala Bailur, Bangalore (IN); Min Suet Lim, Gelugor (MY); Tongyan Zhai, Portland, OR (US); Chee Chun Yee, Bayan Lepas (MY); Ruander Cardenas, Hillsboro, OR (US); Lance Lin, Taipei (TW); Eng Huat Goh, Paya Terubong (MY); Javed Shaikh, Bengaluru (IN); Jun Liao, Portland, OR (US); Kavitha Nagarajan, Bangalore (IN); Tin Poay Chuah, Bayan Baru (MY); Martin M. Chang, Beaverton, OR (US); Shantanu D. Kulkarni, Hillsboro, OR (US); Telesphor Kamgaing, Chandler, AZ (US)

(21) Appl. No.: 18/216,049

(22) Filed: Jun. 29, 2023

(51) Int. Cl. H05K 7/20; F04D 19/00; F04D 29/52; G06F 1/20

(52) U.S. Cl. CPC H05K 7/202; F04D 19/002; F04D 29/522; G06F 1/203

(57) ABSTRACT

Systems, apparatus, articles of manufacture, and methods are disclosed for cooling electronic devices. An example apparatus includes a fan module for an electronic device. The fan module includes a first cover; a second cover; an input/output (IO) board adjacent the second cover, the second cover and IO board beneath the first cover; and a fan between the first cover and the second cover, the fan to operate above the second cover and a portion of the IO board.

### FIELD OF THE DISCLOSURE

This disclosure relates generally to hardware of thermal management systems for electronic devices and, more particularly, to fan modules for electronic devices.

### BACKGROUND

Electronic devices include heat generating components. Thermal solutions are used to dissipate heat generated by the heat generating components. Thermal solutions include heat pipes, vapor chambers, and fans.

### BRIEF DESCRIPTION OF THE DRAWINGS

FIG. 1 is a top view of a portion of an example electronic device with example fan modules and example input/output (IO) ports in accordance with teachings of this disclosure.

FIG. 2 is a bottom view of the portion of the electronic device of FIG. 1.

FIG. 3 is an exploded view of one of the example fan modules of FIG. 1 and an example IO board disclosed herein.

FIG. 4 is an enlarged view of a portion of the electronic device of FIG. 1 showing one of the example fan modules and an example IO board disclosed herein with the fan top cover removed.

FIG. 5 is a perspective view of the example fan module and the example IO board of FIG. 4.

FIG. 6 is a schematic illustration of a cross-sectional view of a portion of a conventional electronic device.

FIG. 7 is a schematic illustration of a cross-sectional view of a portion of an example electronic device including one of the example fan modules of FIG. 1.

FIG. 8 is an enlarged perspective view of a portion of an example fan housing of one of the example fan modules of FIG. 1.

FIG. 9 is an enlarged side view of the example fan housing of the example fan module of FIG. 8.

In general, the same reference numbers will be used throughout the drawing(s) and accompanying written description to refer to the same or like parts. The figures are not necessarily to scale.

### DETAILED DESCRIPTION

Thermal solutions for electronic devices such as, for example, laptop computers, are important features used to cool the heat generating components within the electronic devices and enhance the user experience. Electronic devices that become too hot experience performance issues and/or create an unfavorable user experience. Cooling of the electronic devices also enables greater operating power and/or improved performance.

Disclosed herein are example fan modules for electronic devices that include larger fans that have a wider or increased footprint than traditional fans. The larger fans increase or generate larger airflow compared to traditional fans. The increased airflow allows for increased cooling capacity without increasing a thickness (e.g., a Z-height) of the electronic device. In examples disclosed herein, fan modules are replaceable, repairable, and/or reusable, which enhances sustainability of the electronic devices.

Some electronic devices disclosed herein include an input/output (IO) board that includes ports to enable external devices to couple to the electronic device. Some example ports include universal serial bus (USB) ports, Thunderbolt ports, DisplayPort (DP) interfaces, etc. Some ports enable a large amount of data and/or power transfer, which generates heat. Examples disclosed herein generate airflow (e.g., induce and/or force airflow) over the IO board to enhance cooling of the peripheral device ports and interfaces.

FIG. 1 is a top view of a portion of an example electronic device 100 with example fan modules. The fan modules of the illustrated example include an example first fan module 102 constructed in accordance with teachings of this disclosure and an example second fan module 104 (e.g., a conventional fan module). The first fan module 102 of the illustrated example includes a first fan 106, and the second fan module 104 of the illustrated example includes a second fan 108.

As used herein, x-direction refers to a direction along a width of the electronic device 100 (e.g., a direction between lateral or side edges), y-direction refers to a direction along a length of the electric device 100 (e.g., a direction between a front edge and a rear edge of an electronic device), and z-direction refers to a direction along a height or thickness of the electronic device 100. References to the x-y-z direction throughout this specification pertain a direction along the width, the length, and the thickness or Z-, respectively.

In this example, the first fan module 102 has a first width (e.g., in an x-direction), and the second fan module 104 has a second width (e.g., in the x-direction). The second width is less than the first width. In this example, the first width is 90 millimeters (mm), and the second width is 77.6 mm. Thus, in this example, the first fan module 102 has a width increase of 14% compared to the second fan module 104. The first fan module 102 also has an increased length (e.g., in the y-direction) compared to the second fan module 104. For example, the first fan module 102 has a first length of 90 mm, and the second fan module 104 has a second length of 84 mm. The first fan module 102 and the second fan module 104 have the same thickness or Z-height. In some examples, the Z-height is 7.8 mm. Thus, the larger first fan module 104 does not increase the thickness or Z-height of the electronic device 100. Overall, in this example, the first fan module 102 has a size or footprint of (90 mm by 90 mm by 7.8 mm), and the second fan module 104 has a size or footprint of (77.6 mm by 84 mm by 7.8 mm). Thus, in this example, the first fan module 102 is about 20% larger in size (e.g., footprint) than the second fan module 104. Additionally, the cooling capacity or performance of the first fan module 102 is larger than the cooling capacity or performance of the second fan module 104.

Fan performance could be directly scaled by increasing its blade diameter (e.g., see equations 1-4 below). Assuming that the original blade diameter of the 77 mm fan is 55 mm, and the diameter of the 90 mm fan has a blade diameter of 62 mm, a flowrate generated by the 90 mm fan could increase by 22% compared to the original 77 mm fan. Increasing the fan size could directly improve the system performance by adding or generating more airflow to the system.

$$Volume Flow$$

$${q}_{v 2} = {q}_{v 1} \times {( \frac{{n}_{2}}{{n}_{1}} )}^{1} \times {( \frac{{d}_{2}}{{d}_{1}} )}^{3} \qquad Eqn . 1$$

$$Pressure$$

$${p}_{2} = {p}_{1} \times {( \frac{{n}_{2}}{{n}_{1}} )}^{2} \times {( \frac{{d}_{2}}{{d}_{1}} )}^{2} \times {( \frac{{ρ}_{2}}{{ρ}_{1}} )}^{1} \qquad Eqn . 2$$

$$Absorbed Power$$

$${P}_{R 2} = {P}_{R 1} \times {( \frac{{n}_{2}}{{n}_{1}} )}^{3} \times {( \frac{{d}_{2}}{{d}_{1}} )}^{5} \times {( \frac{{ρ}_{2}}{{ρ}_{1}} )}^{1} \qquad Eqn . 3$$

$$Sound Power Level$$

$${PWL}_{2} = {PWL}_{1} + 70 {log}_{10} ( \frac{{d}_{2}}{{d}_{1}} ) + 55 {log}_{10} ( \frac{{n}_{2}}{{n}_{1}} ) \qquad Eqn . 4$$

In the foregoing equations: qᵥ₁ represents the flow rate in a first state (e.g., measured in cubic feet per minute (CFM)), qᵥ₂ represents the flow rate in a second state (in CFM), n₁ represents fan speed in a first state (e.g., measured in revolutions per minute (RPM)), n₂ represents the fan speed in a second state (in RPM), d₁ represents the fan diameter in a first state (e.g., measured in mm), d₂ represents the fan diameter in a second first state (in mm), p₁ represents the pressure in a first state (e.g., measured in inches of water (inH₂O)), p₂ represents the pressure in a second state (in inH₂O), p₁ represents the density in a first state (e.g., measured in kilograms per cubic meter (kg/m³)), p₂ represents the density in a second state (in kg/m³), P_{R1} represents the absorbed power in a first state (e.g., measured in Watts (W) or milliwatts (mW)), P_{R2} represents the absorbed power in a second state (in W or W), PWL₁ represents the sound power level in a first state (e.g., measured in decibels (dB) or A-weight decibels (dBA), and PWL₂ represents the sound power level in a second state (in dB or dBA).

The first fan module 102 of the illustrated example includes an example first cover 110. In some examples, the first cover 110 is referred to as an upper or top cover. The electronic device 100 of the illustrated example includes a plurality of example input/output (IO) ports 112. In this example, the IO ports 112 are positioned beneath the first cover 110. The second fan module 104 of the illustrated example also includes a cover or top plate 114 that is smaller in size than the first cover 110 of the first fan module 102.

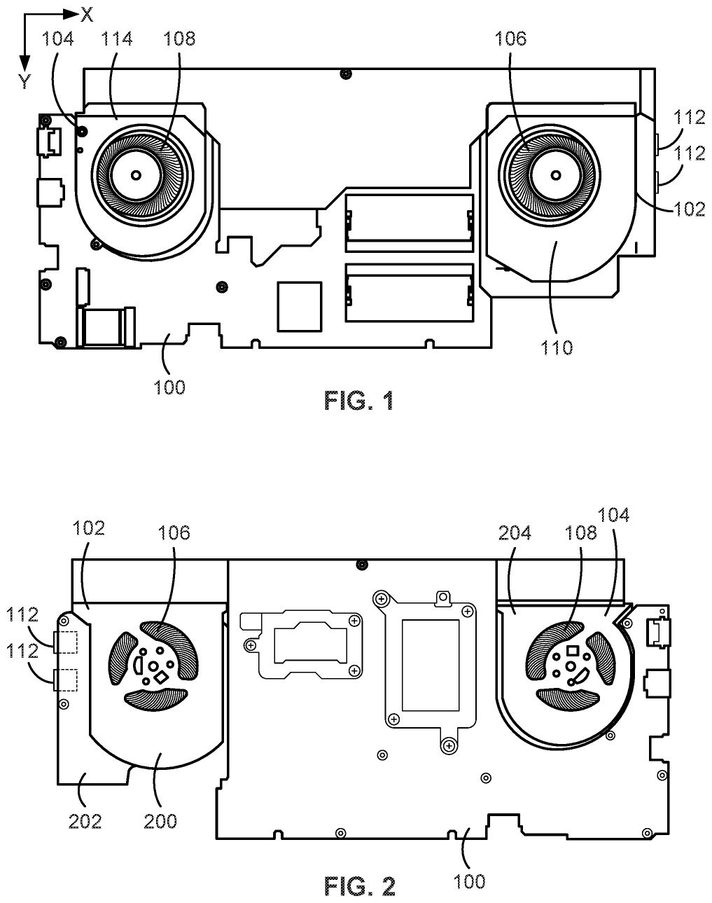

FIG. 2 is a bottom view of the electronic device 100 of FIG. 1. The first fan module 102 of the illustrated example includes an example second cover 200. In some examples, the second cover 200 is referred to as a lower or bottom cover. The first fan module 102 of the illustrated example also includes an example IO board 202. The IO board 202 of the illustrated example supports the IO ports 112. The second fan module 104 of the illustrated example also includes a cover or bottom plate 204 that is smaller in size than the second cover 200 and IO board 202 of the first fan module 102.

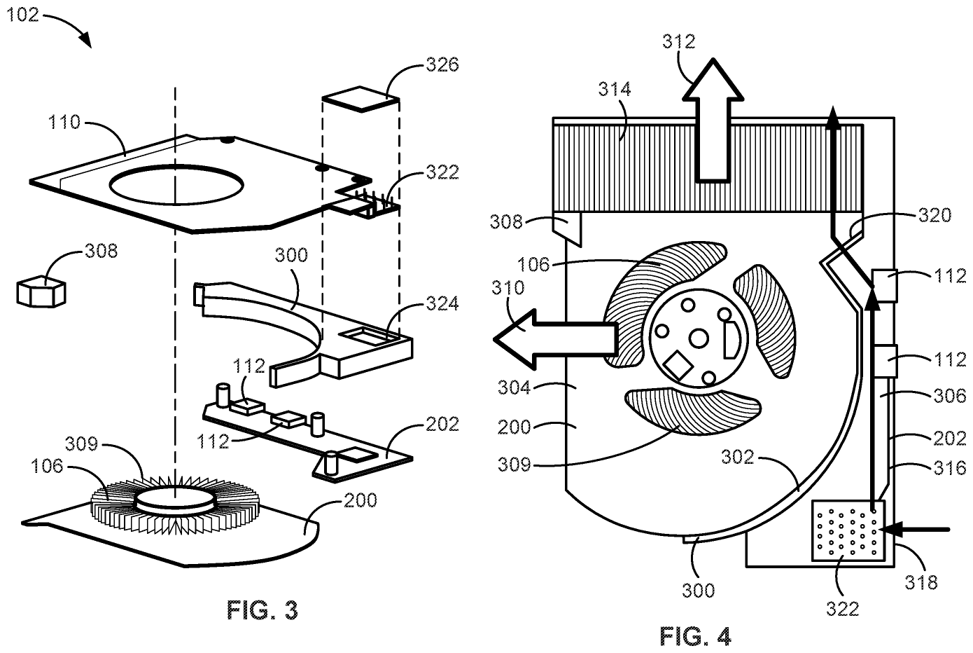

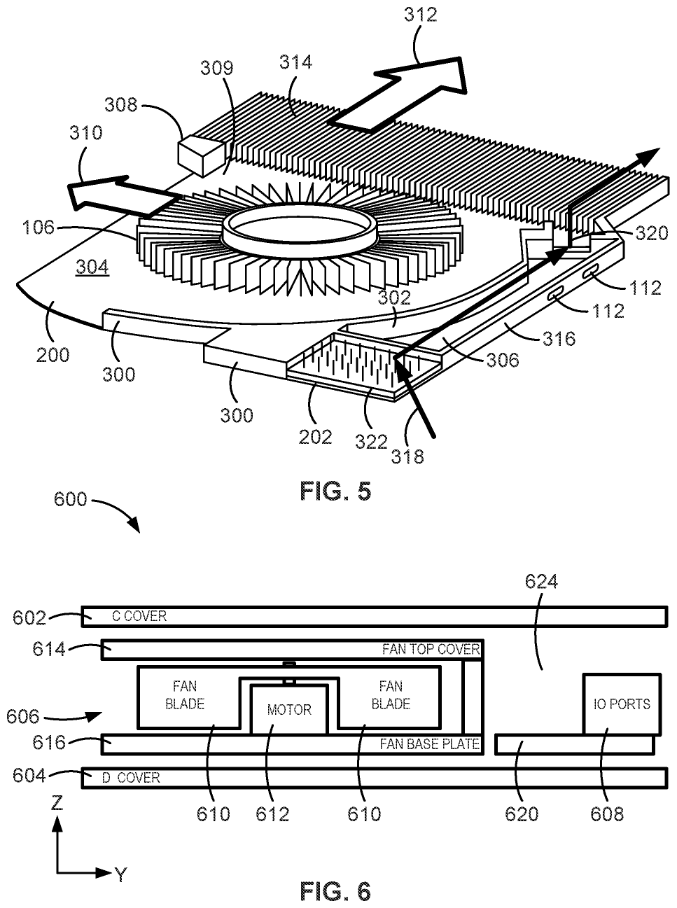

FIG. 3 is an exploded view of the first fan module 102 of FIGS. 1 and 2. FIG. 4 is an enlarged view of a portion of the electronic device 100 of FIG. 1 showing the first fan module 102 with the first cover 110 removed. FIG. 5 is a perspective view of the portion of the electronic device 100 of FIG. 4. Referring to FIGS. 3-5, the first fan module 102 of the illustrated example includes an example fan housing 300. The fan housing 300 of the illustrated example includes an example first wall 302. The wall 302 of the illustrated example forms a divide or partition between an example first or fan compartment 304 (FIGS. 4 and 5) and an example second or IO compartment 306 (FIGS. 4 and 5). The first fan module 102 of the illustrated example includes an example cutwater 308. The first wall 302 and the cutwater 308 define a volute of the first fan 106.

The first fan 106 of the first fan module 102 of the illustrated example has an inlet 309 to draw or intake air, a first fan outlet 310 and a second fan outlet 312 to expel or discharge air. In some examples, the first outlet 310 may be referred as the main outlet. The first fan 106 expels or exhausts air from (e.g., out of) the first outlet 310 and the second outlet 312. In some examples, the first outlet 310 and the second outlet 312 may be referred to as exhaust outlets. The airflow created by the first fan module 102 in the fan compartment is a forced airflow. In the context of this disclosure, “forced” airflow is the flow of air expelled by a fan. Thus, in this example, airflow downstream from the fan is forced air. The electronic device 100 also includes an example plurality of fins 314 at or near the second outlet 312. Heat generating components in the electronic device 100 are thermally coupled to the fins 314. Air exhausted by the first fan 106 flows over the fins 314 and expels or dissipates heat from the fins 314 of the electronic device 100. In some examples, the first fan 106 creates high air speed and low pressure at the second outlet 312 and/or over the fins 314. Additionally, the wall 302 impedes, restricts, or otherwise blocks airflow in the fan compartment 304 from flowing directly across or into the IO compartment 306. Thus, forced airflow generated by the fan does not flow across the IO components 112 positioned in the IO compartment 306.

In the illustrated example, the IO housing 300 includes a housing inlet or simply inlet 318 and an example third outlet 320 (e.g. a housing outlet) in communication with the IO compartment 306. Additionally, the third outlet 320 is in fluid communication with the second fan outlet 312. Thus, a pressure of the third outlet 320 is similar or equal to (e.g., influenced by) a pressure of the airflow at the second fan outlet 312. To the contrary, a pressure of fluid or air at the inlet 318 is greater than a pressure of the air or fluid at the third outlet 320. Thus, the low pressure at the second outlet 312 and the third outlet 320 induces higher pressure air at the inlet 318 to flow through the IO compartment 306. Thus, the airflow created by the first fan module 102 in the IO compartment is induced airflow. In the context of this disclosure “induced” airflow is the flow of air indirectly caused by a fan (e.g., via a pressure differential between a pressure at the inlet 318 and a pressure at the third outlet 320) and not the flow of air directly from a fan outlet. The fan housing 300 of the illustrated example includes an example second wall 316 that has the example inlet 318. The fan housing 300 also includes the example third outlet 320. The first fan 106 induces (e.g., draws) airflow into the IO compartment 306 through the inlet 318, through the IO compartment 306, and out the third outlet 320 to the low pressure area. The wall 302 restricts, blocks or impedes the induced airflow in the IO compartment 304 from flowing into the fan compartment 304. In some examples, the airflow through the third outlet 320 extends over or flows across the fins 314. In some examples, the third outlet 320 may be referred to as an exhaust outlet. The induced airflow in the IO compartment 306 is a closed loop airflow along a chassis edge of the electronic device 100. The induced airflow cools a temperature of and/or removes heat from the IO ports 112.

In some examples, additional components can be incorporated in the IO compartment 306 of the electronic device 100 due to the cooling along the chassis edge from the induced airflow. For example, a retimer or redriver can be connected in the IO compartment 306. In addition, with the first fan module 102 of the present disclosure, retimers or redrivers with greater operating capacity can be used without causing overheating of the electronic device 100. For example, a retimer with a data rate of 80 gigabytes per second (Gbps) could be used in the electronic device 100 in place of a 40 Gbps retimer. The 80 Gbps retimer may produce an extra 500 mW of power and associated heat. Excess heat generated by the 80 Gbps placed in the IO compartment 306 is dissipated and/or removed from the IO compartment 306 by the induced airflow (e.g., cooling providing the induced airflow).

In some examples, the first cover 110 includes an example plurality of pin fins 322. In some examples, the pin fins 322 are located on a recessed portion of the first cover 110 that extends through an example opening 324 in the fan housing 300 into a position near or on the IO board 202. In other examples, the pin fins 322 may be disposed on and/or otherwise coupled to the IO board 202. The induced airflow into the IO compartment 306 flows past the pin fins 322 to dissipate heat from heat generating components that are thermally coupled to the pin fins 322. Thus, in some examples, the pin fins 322 function similarly to the fins 314 to facilitate and/or increase dissipation of heat from the electronic device 100. In some examples, the first fan module 102 includes an example seal 326. The seal 326 is positioned on the first cover 110 over the fin pins 322. In some examples, the seal 326 includes mylar. In some examples, the IO compartment 306 is sealed from the fan compartment 304 (e.g., via O-rings, gaskets, thermal paste, etc.).

FIG. 6 is a schematic illustration of a cross-sectional view of a portion of a conventional electronic device 600 (e.g., taken along a y-z plane). The conventional electronic device 600 includes a first or C cover 602, a second or D cover 604, a fan module 606 and IO ports 608 positioned between the C cover 602 and the D cover 604. The fan module 606 includes fan blades 610 and a motor 612 between a fan top cover 614 and a fan bottom cover 616. The conventional electronic device 600 includes a wall 618 positioned at an edge of the fan bottom cover 616. The wall 618 is separate from an IO board 620 that supports the IO ports 608. In other words, the wall 618 isolates the IO board 620 and the fan module 606. For example, the wall 618 impedes or blocks airflow generated by the fan module 606 from flowing toward the IO board 620. Thus, the fan module 606 creates airflow in a fan compartment 622 but does not create airflow in an IO compartment 624. Thus, heat generated by the connection of peripheral devices to the IO ports 608 is not dissipated by operation of the fan module 606. In some examples, the fan module 606 is implemented by the second fan module 104 of FIG. 1.

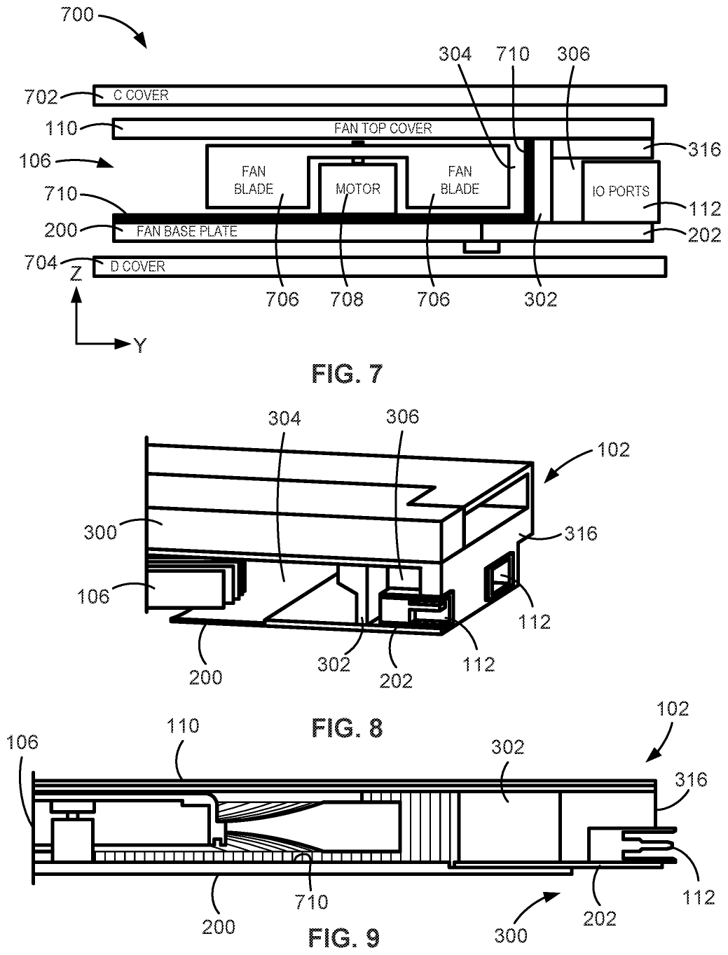

FIG. 7 is a schematic illustration of a cross-sectional view of an electronic assembly 700 implemented with a portion of the example electronic device 100 including the first fan module 102 of FIG. 1 (e.g., taken along a y-z plane). The example electronic assembly 700 of the illustrated example can be a laptop, a tablet, a desktop, a mobile device, a cell phone, a smart phone, a hybrid or convertible PC, a personal computing (PC) device, a sever, a modular computing device, a digital picture frame, a graphic calculator, a smart watch, and/or any other electronic device that employs active cooling or a fan.

The electronic assembly 700 includes an example first device cover 702, which may be a C cover. The electronic assembly 700 also includes an example second device cover 704, which may be a D cover. The first module 102 and the IO ports 112 are between (e.g., positioned within a cavity formed between) the first device cover 702 and the second device cover 704.

The fan module 102 includes the first fan 106 that includes example fan blades 706 and an example motor 708 between the first cover 110, which serves as a fan top cover, and the second cover 200, which serves as a fan bottom cover. The electronic device 100 includes the IO board 202 that supports the IO ports 112. The IO ports 112 are between the first cover 110 and the IO board 202. The electronic device 100 includes the first wall 302 positioned between the first cover 110 and the IO board 202. The first wall 302 separates the first fan module 102 into the fan compartment 304 and the IO compartment 306. Because the first wall 302 is positioned on the IO board 202, a portion of the IO board 202 is in or forms a boundary of the fan compartment 304. Effectively, a portion of the IO board 202 replaces a portion of the fan plate or the second cover 200. Thus, the first fan module 102 and the IO board 202 at least partially overlap. In some examples, the IO board 202 is covered with a protective insert. In some examples, the protective insert is a thin layer of plastic such as, for example, a thin layer of liquid crystal polymer. In some examples, the protective insert is 0.2 mm thick (e.g., in the z-direction). The first fan module 102 also includes the second wall 316 that supports the IO ports 112.

The first fan module 102 creates airflow in a fan compartment 304 and in the IO compartment 306. The airflow created in the fan compartment 304 is forced airflow, and the airflow created in the IO compartment 306 is induced airflow, as disclosed above. Thus, in addition to dissipating heat generated by internal components (i.e., a central processing unit (CPU), a graphics processing unit (GPU), etc.) through the forced airflow, the heat generated by the connection of peripheral devices to the IO ports 112 is dissipated by the induced airflow created by operation of the first fan module 102.

The position of the first wall 302 on the IO board 202 allows the first fan module 102 to have a wider width and, thus, greater size than the conventional fan module 606 in the conventional electronic device 600 of FIG. 6. The first fan module 102 can, therefore, create a larger airflow (e.g., airflow having larger volume). The Z-height of the electronic device 100 is not greater than the Z-height of the conventional electronic 600 even though the electronic device 100 includes a larger fan. In addition, there may be the same number of IO ports 112 in the electronic device 100 as the number of IO ports 608 in the conventional electronic device 600. Thus, the first fan module 102 with the increased fan size does not compromise IO port count and/or require redistribution of IO ports about the electronic device 100. Thus, the width conflict between the first fan module 102 and the IO board 202 is solved when the first wall 302 is positioned over the IO board 202 to allow for a larger fan with the same IO port count.

The first fan module 102 also includes an insulation layer 710. In some examples, the insulation layer 710 is coupled to a side of the first wall 302, the second cover 210, and/or a portion of the IO board 202 within the fan compartment 304. The insulation layer 710 of the illustrated example is oriented toward the fan module 102 and/or the fan compartment 304. In some examples, the insulation layer 710 is on the second cover 210 and the portion of the IO board 202 within the fan compartment 304 and not the first wall 302. The insulation layer 710 ensures there are no gaps or steps beneath the first fan 106. The insulation layer 710 allows the tall components to slightly bump out inside the first fan 106 without increasing the total height of the first fan 102 due to the overlapped components (i.e., the insulation payer 710 covering any taller components). The insulation layer 710 creates a smooth surface within the first fan module 102. The smooth surfaces decreases turbulence and allows for smoother or more laminar airflow. In some examples, the insulation layer 710 is a film. In some examples, the insulation layer 710 includes silicon rubber. In some examples, the insulation layer 710 includes an insert molded plastic. In some examples, the insulation layer is 0.05 mm thick (e.g., in the z-direction).

FIG. 8 is an enlarged perspective view of a portion of the example fan housing 300 of the first fan module 102 of FIG. 1. FIG. 9 is an enlarged side view of the fan housing 300 of the first fan module 102 of FIG. 8. The fan housing 300 includes the second wall 316. The second wall 316 provides a connection stiffener to support the IO ports 112. In some examples, the second wall 316 is used as a connection stiffener to prevent separation of the IO ports 112 (e.g., from the IO board 202). Conventional devices use a separate metal stiffening connector to support IO ports such as, for example, a metal rod or bar. A discrete or separate stiffening connector is not needed with the disclosed examples because the second wall 316 provides the stiffening and support functions. Thus, with the second wall 316 as the port stiffener, less components are used in the electronic device 100.

The first fan module 102 is larger than the second fan module 104. Thus, the first fan module 102 can create a larger airflow than the second fan module 104. The larger airflow results in lower junction temperature, lower GPU and/or CPU temperature, and/or lower skin temperature at the surface of the electronic device 100. The lower temperatures lead to increased GPU and/or CPU performance. The lower temperatures also enable higher power consumption capability and/or the use of high data rate file transmission peripherals, extended power range charging, faster charging rates, and/or high resolution displays without compromising performance of the electronic device 100.

From the foregoing, it will be appreciated that example systems, apparatus, articles of manufacture, and methods have been disclosed that enhance thermal capacity and/or cooling capabilities of electronic devices. Disclosed systems, apparatus, articles of manufacture, and methods improve the efficiency of using a computing device by increasing cooling capability of the electronic device to allow for more power consumption and/or heat generation without increasing a size (e.g., a footprint, a thickness, etc.) of the electronic device, reducing batter life, reducing the number of IO ports, redistributing IO ports and potentially moving cables closer to the user, lowering charging capability and/or charging rate, and/or adding more components such as heat pipes to the IO ports. Thus, disclosed systems, apparatus, articles of manufacture, and methods are accordingly directed to one or more improvement(s) in the operation of a machine such as a computer or other electronic and/or mechanical device.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

Example systems, apparatus, articles of manufacture, and methods are disclosed for cooling electronic devices. Example 1 includes a fan module for an electronic device. The fan module includes a first cover; a second cover; an input/output (IO) board adjacent the second cover, the second cover and IO board positioned beneath the first cover; and a fan between the first cover and the second cover, the fan to operate above the second cover and a portion of the IO board.

Example 2 includes the fan module of Example 1, further including a housing having a wall coupled to the IO board, the wall defining a first compartment and a second compartment.

Example 3 includes the fan module of Example 2, wherein the fan is in the first compartment, the fan is to create forced airflow in the first compartment, and the fan to create induced airflow in the second compartment.

Example 4 includes the fan module of Example 3, wherein the second compartment includes one or more IO ports.

Example 5 includes the fan module of any of Examples 2-4, further including an insulation layer on the second cover, the portion of the IO board, and a side of the wall oriented in the first compartment.

Example 6 includes the fan module of any of Examples 2-5, wherein the second compartment includes an inlet and a plurality of pin fins adjacent the inlet.

Example 7 includes the fan module of any of Examples 2-6, wherein the wall is a first wall and the housing includes a second wall, the second wall to support one or more IO ports.

Example 8 includes the fan module of any of Examples 2-7, wherein the first compartment includes a first exhaust outlet and a second exhaust outlet, and the second compartment includes a third exhaust outlet.

Example 9 includes the fan module of Example 8, wherein the fan is to create a low pressure at the second exhaust outlet and the third exhaust outlet.

Example 10 includes the fan module of either of Examples 8 or 9, further including a plurality of fins at or near the second exhaust outlet and the third exhaust outlet.

Example 11 includes an apparatus to cool an electronic device. The apparatus includes a first compartment; a second compartment; a wall separating the first compartment and the second compartment; and a fan positioned in the first compartment, the fan to exhaust air from the first compartment and induce airflow in the second compartment.

Example 12 includes the apparatus of Example 11, further including a first cover over the first compartment and the second compartment.

Example 13 includes the apparatus of Example 12, further including a second cover beneath the first compartment, and an input/output (IO) board beneath the second compartment, a portion of the IO board positioned in the first compartment.

Example 14 includes the apparatus of Example 13, further including an insulation layer on the second cover and the portion of the IO board beneath the first compartment.

Example 15 includes the apparatus of any of Examples 11-14, further including an input/output (IO) board beneath the first compartment and the second compartment.

Example 16 includes the apparatus of any of Examples 11-15, wherein the wall is a first wall, the apparatus further including: one or more input/output (IO) ports in the second compartment; and a second wall including a connection stiffener for the one or more IO ports.

Example 17 includes the apparatus of any of Examples 11-16, further including an insulation layer on the wall in the first compartment.

Example 18 includes the apparatus of any of Examples 11-17, wherein the first compartment has a first outlet and the second compartment has a second outlet, the second outlet adjacent the first outlet, the fan to create a low pressure at the first outlet and adjacent second outlet, the low pressure to induce the airflow in the second compartment.

Example 19 includes the apparatus of any of Examples 11-18, wherein the induced airflow is a closed loop airflow along a chassis edge of the electronic device.

Example 20 includes a fan module for an electronic device that includes a first cover; a second cover coupled to the first cover; a housing positioned between the first cover and the second cover, the housing having a wall defining a first compartment and a second compartment; a fan positioned in the first compartment, the fan having a fan inlet and a fan outlet, the fan to generate forced airflow through the first compartment between the fan inlet and the fan outlet, the fan to cause a low pressure at the fan outlet; and an input/output (IO) compartment having IO components positioned in the second compartment, the wall restricting the forced airflow from the first compartment to the second compartment, the housing having a housing inlet and a housing outlet in fluid communication with the second compartment, the housing outlet being in fluid communication with the fan outlet such that the low pressure at the fan outlet causes a pressure differential between the housing inlet and the housing outlet to induce airflow in the IO compartment from the housing inlet to the housing outlet, the wall restricting the induced airflow from the second compartment to the first compartment, the induced airflow to remove heat generated by the IO components positioned in the second compartment.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A fan module for an electronic device, the fan module comprising:
a first cover;
a second cover;
an input/output (IO) board adjacent the second cover, the second cover and IO board positioned beneath the first cover; and
a fan between the first cover and the second cover, the fan to operate above the second cover and a portion of the IO board.

2. The fan module of claim 1, further including a housing having a wall coupled to the IO board, the wall defining a first compartment and a second compartment.

3. The fan module of claim 2, wherein the fan is in the first compartment, the fan is to create forced airflow in the first compartment, and the fan to create induced airflow in the second compartment.

4. The fan module of claim 3, wherein the second compartment includes one or more IO ports.

5. The fan module of claim 2, further including an insulation layer on the second cover, the portion of the IO board, and a side of the wall oriented in the first compartment.

6. The fan module of claim 2, wherein the second compartment includes an inlet and a plurality of pin fins adjacent the inlet.

7. The fan module of claim 2, wherein the wall is a first wall and the housing includes a second wall, the second wall to support one or more IO ports.

8. The fan module of claim 2, wherein the first compartment includes a first exhaust outlet and a second exhaust outlet, and the second compartment includes a third exhaust outlet.

9. The fan module of claim 8, wherein the fan is to create a low pressure at the second exhaust outlet and the third exhaust outlet.

10. The fan module of claim 8, further including a plurality of fins at or near the second exhaust outlet and the third exhaust outlet.

11. An apparatus to cool an electronic device, the apparatus comprising:
a first compartment;
a second compartment;
a wall separating the first compartment and the second compartment; and
a fan positioned in the first compartment, the fan to exhaust air from the first compartment and induce airflow in the second compartment.

12. The apparatus of claim 11, further including a first cover over the first compartment and the second compartment.

13. The apparatus of claim 12, further including a second cover beneath the first compartment, and an input/output (IO) board beneath the second compartment, a portion of the IO board positioned in the first compartment.

14. The apparatus of claim 13, further including an insulation layer on the second cover and the portion of the IO board beneath the first compartment.

15. The apparatus of claim 11, further including an input/output (IO) board beneath the first compartment and the second compartment.

16. The apparatus of claim 11, wherein the wall is a first wall, the apparatus further including:
one or more input/output (IO) ports in the second compartment; and
a second wall including a connection stiffener for the one or more IO ports.

17. The apparatus of claim 11, further including an insulation layer on the wall in the first compartment.

18. The apparatus of claim 11, wherein the first compartment has a first outlet and the second compartment has a second outlet, the second outlet adjacent the first outlet, the fan to create a low pressure at the first outlet and adjacent second outlet, the low pressure to induce the airflow in the second compartment.

19. The apparatus of claim 11, wherein the induced airflow is a closed loop airflow along a chassis edge of the electronic device.

20. A fan module for an electronic device comprising:
a first cover;
a second cover coupled to the first cover;
a housing positioned between the first cover and the second cover, the housing having a wall defining a first compartment and a second compartment;
a fan positioned in the first compartment, the fan having a fan inlet and a fan outlet, the fan to generate forced airflow through the first compartment between the fan inlet and the fan outlet, the fan to cause a low pressure at the fan outlet; and
an input/output (IO) compartment having IO components positioned in the second compartment, the wall restricting the forced airflow from the first compartment to the second compartment, the housing having a housing inlet and a housing outlet in fluid communication with the second compartment, the housing outlet being in fluid communication with the fan outlet such that the low pressure at the fan outlet causes a pressure differential between the housing inlet and the housing outlet to induce airflow in the IO compartment from the housing inlet to the housing outlet, the wall restricting the induced airflow from the second compartment to the first compartment, the induced airflow to remove heat generated by the IO components positioned in the second compartment.
